(19) United States
(12) Patent Application Publication
(10) Pub. No.: US 2015/0049126 A1
(43) Pub. Date: Feb. 19, 2015

(54) PIXEL, PIXEL DRIVING METHOD, AND DISPLAY DEVICE USING THE SAME

(71) Applicant: SAMSUNG DISPLAY CO., LTD., Yongin-City (KR)

(72) Inventor: Dong-Hun JUNG, Yongin-City (KR)

(73) Assignee: SAMSUNG DISPLAY CO., LTD., Yongin-City (KR)

(21) Appl. No.: 14/277,963

(22) Filed: May 15, 2014

(30) Foreign Application Priority Data
Aug. 14, 2013 (KR) 10-2013-0096653

(51) Int. Cl. G09G 3/32; H01L 27/32

(52) U.S. Cl. CPC G09G 3/3241; H01L 27/3276
USPC 345/690; 315/172; 257/40

(57) ABSTRACT

A pixel includes a first transistor, an organic light emitting diode, and a second transistor having a terminal connected between the first transistor and the organic light emitting diode. The first transistor is a driving transistor. The second transistor controls flow of leakage current along a signal path that bypasses the organic light emitting diode.

### CROSS-REFERENCE TO RELATED APPLICATION

Korean Patent Application No. 10-2013-0096653, filed on Aug. 14, 2013, in the Korean Intellectual Property Office, and entitled, “Pixel, Pixel Driving Method, and Display Device Using The Same,” is incorporated by reference herein in its entirety.

### BACKGROUND

1. Field

One or more embodiments described herein relate to a display device.

2. Description of the Related Art

Various types of displays are used in portable information terminals such as a personal computers, mobile phones, or personal digital assistants. Among them, organic light emitting displays have demonstrated improved light emission efficiency, luminance, viewing angles, and response speeds.

The pixels in an organic light emitting display use organic light emitting diodes to emit light. The organic light emitting diodes generate light having predetermined luminance in accordance with a data current supplied to the pixels. The light is generated by one or more transistors and capacitors.

One type of pixel structure uses a plurality of transistors and capacitors to stabilize black luminance or other effects of the display device caused by leakage current. Stabilization of black luminance has required a light emission control signal and a scan signal to turn on/off the transistors. However, as the number of transistors increases, more space must be allocated for signal lines that apply these and other signals to the transistors. Excessive numbers of signal lines not only reduce space efficiency, they complicate the design of the display device and the cost of manufacture.

### SUMMARY

In accordance with one embodiment, a pixel includes a switching transistor including a source electrode connected to a data line, the switching transistor configured to perform a switching operation based on a first scan signal; a driving transistor including a source electrode connected to a drain electrode of the switching transistor, the driving transistor configured to control a driving current based on a data signal transmitted when the switching transistor is turned on; a first light emission transistor including a source electrode connected to a drain electrode of the driving transistor, the first light emission transistor configured to perform a switching operation based on a first light emission signal; an inverter configured to invert the first light emission signal to generate a second light emission signal; and an organic light emitting diode configured to emit light based on the driving current. The pixel also includes a bypass transistor including a source electrode connected to an anode electrode of the organic light emitting diode, the bypass transistor configured to perform a switching operation based on the second light emission signal.

In the pixel, a drain electrode of the bypass transistor may be connected to a first voltage source supplying an initialization voltage, and the bypass transistor may be turned on based on the second light emission signal to allow leakage current to flow along a bypass signal path. The pixel may include a storage capacitor connected between a gate of a first driving transistor and a second voltage source.

The pixel may include an initialization transistor connected between a gate electrode of the driving transistor and the first voltage source, the initialization transistor may be configured to perform a switching operation based on a second scan signal.

The pixel may include a compensation transistor connected to the gate electrode and the drain electrode of the driving transistor, the compensation transistor may be configured to perform a switching operation based on the first scan signal. Each of the first scan signal and the second scan signal may include an enable pulse, and the enable pulse of the second scan signal may be before the enable pulse of the first scan signal.

The pixel may include a second light emission transistor connected between a source of the driving transistor and the first voltage source, the second light emission transistor may perform a switching operation based on to the first light emission signal. The first light emission transistor and the second light emission transistor may be turned on after the data signal is transmitted.

In accordance with another embodiment, a method of driving a pixel includes turning off a first light emission transistor and a second light emission transistor based on a first light emission signal; generating a second light emission signal inverted from the first light emission signal; and turning on a bypass transistor based on the second light emission signal, wherein turning on the bypass transistors allows leakage current to flow through the bypass transistor along a bypass signal path.

The method may include turning on a switching transistor based on a first scan signal; turning on a compensation transistor according to the first scan signal; and transmitting a data signal to a gate electrode of a driving transistor through the turned-on switching transistor and compensation transistor. The method may include maintaining a voltage corresponding to the data signal transmitted to the gate electrode of the driving transistor in a storage capacitor based on the data signal.

The method may include turning on an initialization transistor based on the second scan signal; and transmitting an initialization voltage to the gate electrode of the driving transistor. Transmitting the initialization voltage may be performed before the switching transistor and the compensation transistor are turned on.

After the data signal is transmitted to the gate electrode of the driving transistor, the method may include emitting light from an organic light emitting diode based on driving current flowing through the driving transistor.

In accordance with another embodiment, a display device may include a plurality of scan lines, a plurality of light emission control lines, and a plurality of data lines; and a plurality of pixels connected to the scan lines, the light emission control lines, and the data lines, wherein the pixel includes: a switching transistor including a source electrode connected to a data line, the switching transistor configured to perform a switching operation according to a first scan signal; a driving transistor including a source electrode connected to a drain electrode of the switching transistor, the driving transistor configured to control a driving current according to a data signal transmitted when the switching transistor is turned on; a first light emission transistor including a source electrode connected to a drain electrode of the driving transistor, the first light emission transistor configured to perform a switching operation according to a first light emission signal; an inverter configured to invert the first light emission signal to generate a second light emission signal; an organic light emitting diode configured to emit light according to the driving current; and a bypass transistor including a source electrode connected to an anode electrode of the organic light emitting diode, the bypass transistor configured to perform a switching operation according to the second light emission signal.

In the pixel, a drain electrode of the bypass transistor may be connected to a first voltage source supplying an initialization voltage, and the bypass transistor is turned on based on the second light emission signal to allow leakage current to flow along a bypass path. A storage capacitor may be connected between a gate of a first driving transistor and a second voltage source.

The pixel may include an initialization transistor connected between a gate electrode of the driving transistor and the first voltage source, the initialization transistor may be configured to perform a switching operation based on a second scan signal. The pixel may include a compensation transistor connected to the gate electrode and the drain electrode of the driving transistor, the compensation transistor may be configured to perform a switching operation based on the first scan signal. Each of the first and second scan signals may include an enable pulse, and the enable pulse of the second scan signal may be before the enable pulse of the first scan signal.

A second light emission transistor may be connected between a source of the driving transistor and the second voltage source, wherein the second light emission transistor may perform a switching operation based on to the first light emission signal. The first light emission transistor and the second light emission transistor may be turned on after the data signal is transmitted.

In accordance with another embodiment, a pixel includes a first transistor; an organic light emitting diode; and a second transistor having a terminal connected between the first transistor and the organic light emitting diode, wherein the first transistor is a driving transistor and the second transistor controls flow of leakage current along a signal path that bypasses the organic light emitting diode. The second transistor may control flow of leakage current along the bypass signal path during an initialization period of the driving transistor. The second transistor may control flow of leakage current along the bypass signal path during a scan period.

The second transistor may be controlled based on a light emission signal, or an inverted logical value of a light emission signal. The bypass signal path may be coupled to a voltage source. The voltage source may be an initialization voltage source.

### BRIEF DESCRIPTION OF THE DRAWINGS

Features will become apparent to those of skill in the art by describing in detail exemplary embodiments with reference to the attached drawings in which:

FIG. 1 illustrates an embodiment of a display device;

FIG. 2 illustrates an embodiment of a pixel of the display device;

FIG. 3 illustrates an embodiment of waveforms for controlling the pixel; and

FIG. 4 illustrates another embodiment of a pixel of the display device.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

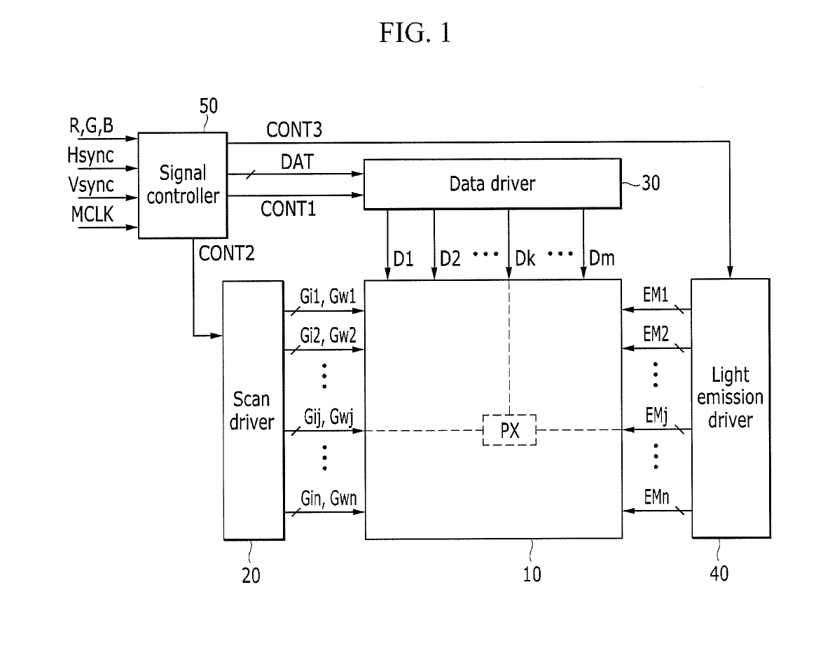

FIG. 1 illustrates another embodiment of a display device 1 which includes a display unit 10, a scan driver 20, a data driver 30, a light emission driver 40, and a signal controller 50. The display unit 10 includes a plurality of pixels PX connected to a plurality of scan lines Gi1-Gin and Gw1-Gwn extending in a first direction (e.g., a row direction) and a plurality of data lines D1-Dm extending in a second direction (e.g., a column direction). In other embodiments, connection structures of the scan lines Gi1-Gin and Gw1-Gwn, data lines, and voltage supply lines may be different from FIG. 1.

Each of the pixels PX may include multiple (e.g., three) subpixels which emit light of a different color, e.g., red R, green G, and blue B. Each of the pixels/subpixels is activated based on scan signals transmitted through corresponding pairs of scan lines Gi1-Gin and Gw1-Gwn. Each subpixel emits light based on a driving current that corresponds to a data signal transmitted through respective data lines D1-Dm, to thereby display an image. When used herein, a pixel may correspond to a pixel or a subpixel.

According to an exemplary embodiment, with respect to the subpixels in each pixel PX, one of the subpixels emits light of one color of red, green, and blue in accordance with a driving voltage source. Each voltage value may be set to reduce power consumption transmitted to the voltage supply lines. That is, in order to realize a color representation, each subpixel in each pixel may alternately display a primary color according to a supplied driving voltage source. An image may therefore be displayed based on a temporal and spatial sum on an entire display unit.

When an image is to be displayed based on a temporal sum, each subpixel of one pixel is temporally displayed as one color of red R, green G, and blue B. Thus, one color is realized according to a plurality of driving voltage sources supplied to respective subpixels. When an image is to be displayed based on a spatial sum, one pixel realizes one color through a combination of three primary colors by three subpixels. The display unit of the entire display panel may display an image of a corresponding frame through a spatial combination of the plurality of pixels PX arranged in a row direction or a column direction.

The signal controller 50 receives image signals R, G, and B from an external source and one or more input control signals. The image signals R, G, and B may include luminance information on each subpixel of each pixel PX. The luminance information may include data indicating a gray scale value of a corresponding pixel or subpixel among a predetermined number of gray scale values, for example, 1024=2¹⁰, 256=2⁸, or 64=2⁶ gray scale values. The input control signals may include a vertical synchronization signal Vsync, a horizontal synchronizing signal Hsync, and/or a main clock MCLK.

The signal controller 50 processes the image signals R, G, and B according to an operation condition of the display unit 10 and the data driver 30 based on image signals R, G, and B and the input control signals. The signal controller 50 generates and outputs a data control signal CONT1, a scan control signal CONT2, a light emission control signal CONT3, and an image data signal DAT. The signal controller 50 transmits the scan control signal CONT2 to the scan driver 20 and the data control signal CONT1 and a plurality of image data signals DAT to the data driver 30.

The scan driver 20 supplies a plurality of scan signals Gi[1]-Gi[n] and Gw[1]-Gw[n] to a respective plurality of scan lines Gi1-Gin and Gw1-Gwn according to the scan control signal CONT2.

The data driver 30 generates data signals (for example, data voltages) according to image data signal DAT based on data control signal CONT1, and supplies the generated data signals to corresponding ones of data lines D1-Dm. Specifically, data driver 30 is synchronized at the time when the scan signal of a gate-on voltage corresponding to each frame is supplied and transmits a plurality of data signals for controlling an emission degree of each of the pixels PX through the data lines D1-Dm. The gate-on voltage may correspond to a level at which a switching transistor in each of the plurality of pixels PX is turned on.

The light emission driver 40 supplies light emission signals EM[1]-EM[n]) to respective light emission control lines EM1-EMn.

Each pixel PX is connected to two scan lines among scan lines Gi1-Gin and Gw1-Gwn, a light emission control line among light emission control lines EM1-EMn, and a data line among data lines D1-Dm. Data voltages corresponding to the image data signal DAT are transmitted to corresponding pixels PX through data lines D1-Dm. Scan signal are transmitted to each pixel PX through corresponding ones of scan lines GIl-Gin and GW1-Gwn. A light emission signal for controlling light emission of the organic light emitting diode (OLED) of the PX is transmitted through a corresponding one of light emission control signals E1-En.

The scan driver 20, data driver 30, light emission driver 40, and signal controller 50 may be electrically connected to display unit 10, and may be mounted to a flexible printed circuit (FPC) or film attached and electrically connected to display unit 10, for example, in the form of a chip. Further, the scan driver 20, data driver 30, light emission driver 40, and signal controller 50 may be directly mounted on a glass substrate of the display unit 10, and may be formed on the same layer(s) as the scan line, data line, voltage supply line, and/or the thin film transistor.

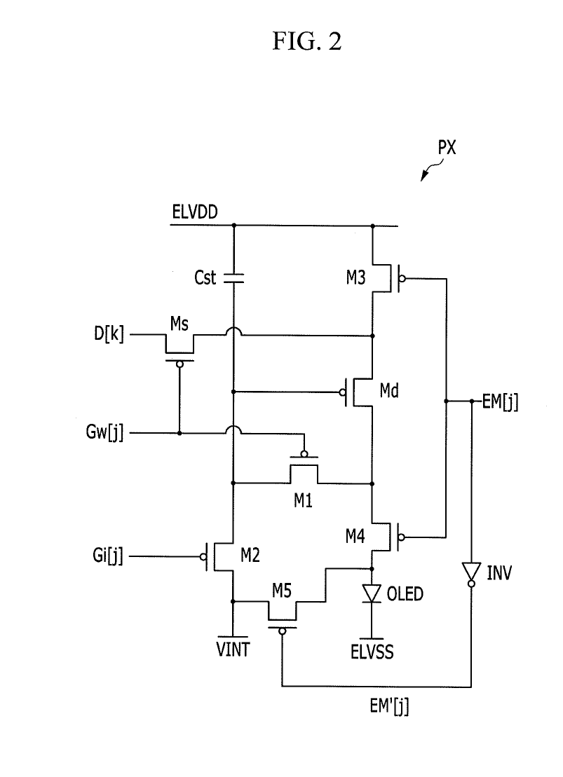

FIG. 2 illustrates an embodiment of a pixel which may be included in the display device of FIG. 1. As illustrated in FIG. 2, pixel PX is connected to a j-th first scan line Gij, a j-th second scan line Gwj, a j-th light emission control line EMj, and a k-th data line Dk. Other pixels in the display unit may be configured in a similar manner.

The pixel PX includes a switching transistor Ms, a driving transistor Md, a compensation transistor M1, an initialization transistor M2, light emission transistors M3 and M4, a bypass transistor M5, a storage capacitor Cst, an organic light emitting diode (OLED), and an inverter INV. A driving voltage source for light emission of the organic light emitting diode (OLED) is applied to a first voltage supply line ELVDD. Voltage values of the driving voltage source applied to the first voltage supply line ELVDD may be different from each other, and may be voltage values preset by the signal controller 50. Although FIG. 2 illustrates transistors Ms, Md, and M1-M5 as p-channel metal oxide semiconductor (PMOS) transistors corresponding to p-channel type transistors, the transistors may be NMOS transistors or NMOS and PMOS transistors may be used to provide a CMOS implementation.

The switching transistor Ms includes a gate electrode connected to scan line Gwj, a source electrode connected to data line Dk, and a drain electrode connected to a source electrode of the driving transistor Md. The switching transistor Ms transmits the data signal D[k] from data line Dk to the source electrode of the driving transistor Md. The switching transistor Ms is turned on by scan signal Gw[j] applied to scan line Gwj.

The driving transistor Md includes a source electrode to which the data voltage is transmitted for a period during which switching transistor Ms is turned on, a gate electrode connected to a first terminal of the storage capacitor Cst, and a drain electrode connected to a source of the light emission transistor M4.

The first terminal of the storage capacitor Cst is connected to a gate electrode of the driving transistor Md, and a second terminal is connected to a voltage source applying the voltage ELVDD.

The compensation transistor M1 includes a gate electrode connected to the scan line Gwj, a drain electrode connected to a gate electrode of the driving transistor Md, and a source electrode connected to a drain electrode of the driving transistor Md. The compensation transistor M1 is turned on by the scan signal applied to the scan line Gwj and diode-connects the driving transistor Md.

The initialization transistor M2 includes a gate electrode connected to scan line Gij, a drain electrode connected to a voltage source supplying an initialization voltage VINT, and a source electrode connected to a gate of the driving transistor Md.

The light emission transistor M3 includes a gate electrode connected to emission control line EMj, a source electrode connected to the voltage source supplying the voltage ELVDD, and a drain electrode connected to a source of driving transistor Md.

The light emission transistor M4 includes a gate electrode connected to light emission control line EMj, a source electrode connected to the drain electrode of the driving transistor Md, and a drain electrode connected to an anode electrode of the organic light emitting diode OLED.

The bypass transistor M5 includes a gate electrode connected to an output terminal of the inverter INV, a drain electrode connected to a voltage source supplying the initialization voltage INV, and a source electrode connected to the anode electrode of the organic light emitting diode OLED.

The inverter INV is connected between the gate electrodes of light emission transistors M3 and M4, and the gate electrode of bypass transistor M5. The inverter INV receives the light emission signal from light emission control line EMj, inverts the received light emission signal, and transmits the inverted light emission signal to the gate electrode of the bypass transistor M5. The inverter INV may include, for example, a bipolar transistor, electric field effect transistor, or insulation gate bipolar transistor.

The organic light emitting diode (OLED) includes an anode electrode connected to the source electrode of the bypass transistor M5 and a cathode electrode connected to a voltage source supplying a voltage ELVSS. When transistors M3 and M4 are turned on by light emission signal EM[j] from light emission control signal EMj, the organic light emitting diode (OLED) emits light according to a current flowing through the driving transistor Md and displays light of an image.

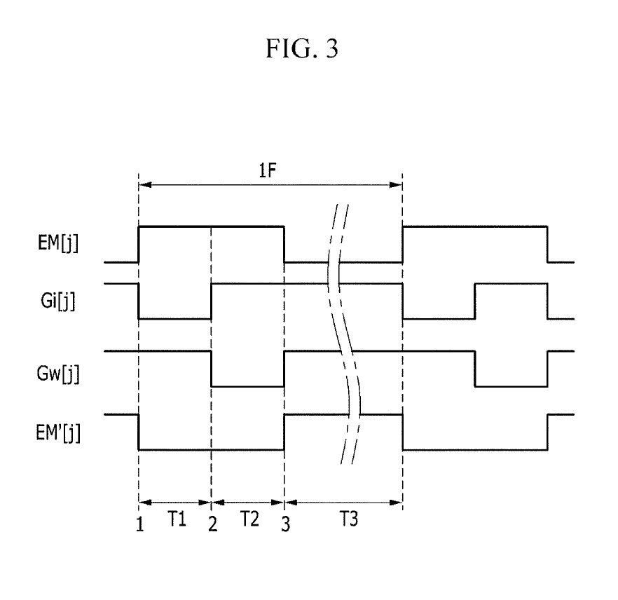

FIG. 3 illustrates an embodiment of waveforms for driving the pixel in FIG. 2.

The signals are shown for a predetermined period which includes one frame period 1F. The waveforms in FIG. 3 correspond to scan lines Gi[j] and Gw[j], light emission signal EM[i], and light emission signal EM[i]. Each of the scan lines Gi[1]-Gi[n] and Gw[1]-Gw[n] includes an enable pulse. In one embodiment, enable pulses of scan lines Gi[1]-Gi[n] and scan lines Gw[1]-Gw[n] are sequentially generated. For illustrative purposes, the level of the enable pulse is shown to be a low level in order to be compatible with the use of p-channel type transistors.

Referring to FIG. 3, a light emission signal of a high level is applied to the light emission control line EMj at a time point 1 of an initialization period T1. Then, the transistors M3 and M4 are turned off, and thus a current does not flow in the driving transistor Md.

Further, at time point 1 of the initialization period T1, inverter INV outputs a light emission signal Em′[j] of a low level (inverted from light emission signal Em[j] of the high level) to the light emission control line EM′j. As a result, the bypass transistor M5 is turned on. When the driving transistor Md is turned off and the bypass transistor M5 is turned on for the initialization period T1 and a scan period T2, a bypass signal path through bypass transistor M5 and the voltage source of the initialization voltage VINT is formed. Accordingly, leakage current completely passes through bypass transistor M5 before a light emission period T3, so that influence of leakage current is reduced or prevented.

Further, at time point 1 of initialization period T1, a low level of scan signal Gi[j] is applied to scan line Gij. As a result, initialization transistor M2 is turned on for the initialization period T1. Thus the gate electrode of the driving transistor Md is initialized by receiving initialization voltage VINT and the storage capacitor Cst is initialized with a voltage ELVDD-VINT.

Subsequently, a low level of scan signal Gw[j] is applied to scan line Gwj at time point 2 of scan period T2. As a result, the switching transistor Ms and compensation transistor M1 are turned on. When the compensation transistor M1 is turned on, the gate and drain of the driving transistor Md are connected to each other by turned-on compensation transistor M1. As a result, the driving transistor Md is diode-connected. Accordingly, a voltage between the gate and source of the driving transistor Md becomes a threshold voltage of the driving transistor Md.

When the switching transistor Ms is turned on, data signal D[k] is applied to the source electrode of the driving transistor Md from data line Dk. When a voltage of the data signal D[k] is Vdata and a threshold voltage of the driving transistor Md is Vth (negative voltage), the gate voltage of the driving transistor Md becomes Vdata+Vth. The voltage of the gate electrode of the driving transistor Md is maintained by the storage capacitor Cst.

At time point 3, a low level of the scan signal EM[j] is applied to light emission control line EMj during light emission period T3. As a result, transistors M3 and M4 are turned on for the light emission period T3. A voltage between the gate and source of the driving transistor Md is as shown in Equation 1. Because the inverter INV inverts the light emission signal EM[j] of the low level and applies the light emission signal EM[j] of the high level to the light emission control line EM′, bypass transistor M5 is turned off. When the driving transistor Md is turned on and bypass transistor M5 is turned off for light emission period T3, the organic light emitting diode OLED emits light.

Vgs=(Vdata+Vth)−ELVDD (1)

In Equation (1), Vgs denotes a voltage between the gate and the source of the driving transistor Md, Vth denotes a threshold voltage of the driving transistor Md, and Vdata denotes a data voltage transmitted from the data line Dm.

At this time, a current flows in the organic light emitting diode OLED through the driving transistor Md, and a value of the current flowing in the organic light emitting diode OLED is as shown in Equation 2.

$$\begin{matrix}IOLED = β / 2 ( Vgs - Vth ) ⋀ 2 \\ = β / 2 ( ( Vdata + Vth ) - ELVDD ) - Vth ) ⋀ 2 \\ = β / 2 ( Vdata - ELVDD ) ⋀ 2\end{matrix} \qquad ( 2 )$$

In Equation 2, IOLED denotes a current flowing in the organic light emitting diode OLED, and β denote a constant value.

Generally, deviation of the threshold voltage Vth of a thin film transistor may be generated for each pixel PX by non-uniformities in the manufacturing process. Consequently, an amount of current supplied to the organic light emitting diode OLED may changed, which may change or otherwise adversely affect light emission luminance. However, from Equation 2, it is evident that variations or other adverse influences from the threshold voltages may be excluded, even though the threshold voltages of driving transistors Md in respective pixels PX are different from each other. As a result, a constant current may be supplied to each of the organic light emitting diode OLEDs. Therefore, a problem of luminance non-uniformity based on a position of the pixel PXs may be avoided.

Although FIG. 3 illustrates that enable pulses of the scan signals Gi[1]-Gi[n] and Gw[1]-Gw[n] have the same width, the widths of the enable pulses may be different tin other embodiments. The enable pulses may be set to have different widths.

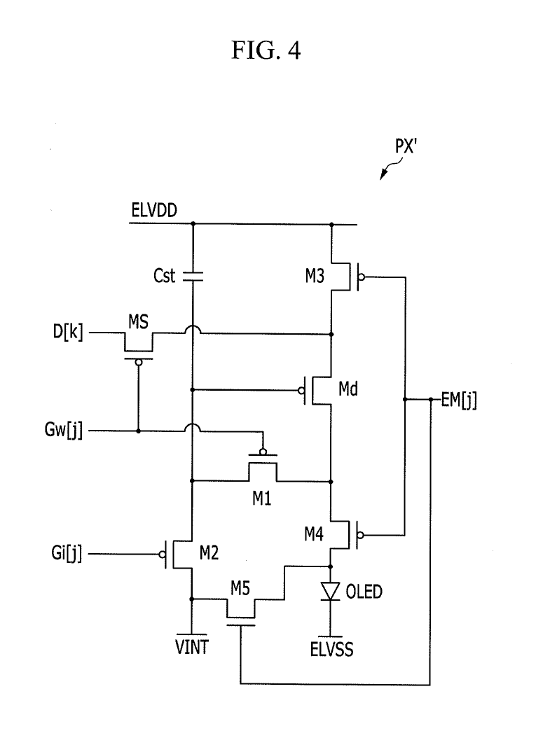

FIG. 4 illustrates another embodiment of a pixel PX′ which, for example, may be included in the display device of FIG. 1. In this embodiment, pixel PX′ does not include inverter INV.

As shown in FIG. 4, bypass transistor M5 is an n-channel metal oxide semiconductor (NMOS) transistor. As such, referring to FIG. 3, light emission signal EM[j] of a high level is applied to light emission control line EMj at time point 1 of initialization period T1 and scan period T2. As a result, the bypass transistor M5 is turned on. When the driving transistor Md is turned off and bypass transistor M5 is turned on for initialization period T1 and scan period T2, a bypass path to bypass transistor M5 and the voltage source of the initialization voltage VINT is formed. Accordingly, a leakage current completely passes through the bypass transistor M5 before light emission period T3, so that an influence of the leakage current is reduced or prevented.

At time point 3 of the light emission period T3, a low level of the light emission signal EM[j] is applied to the light emission control line EMj. As a result, transistors M3 and M4 are turned on during the light emission period T3, and a voltage between the gate and source of driving transistor Md is as shown in Equation (1). The bypass transistor M5 is turned off based on the low level of light emission signal EM[j]. When driving transistor Md is turned on and bypass transistor M5 is turned off for light emission period T3, the organic light emitting diode OLED emits light.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A pixel, comprising:
a switching transistor including a source electrode connected to a data line, the switching transistor configured to perform a switching operation based on a first scan signal;
a driving transistor including a source electrode connected to a drain electrode of the switching transistor, the driving transistor configured to control a driving current based on a data signal transmitted when the switching transistor is turned on;
a first light emission transistor including a source electrode connected to a drain electrode of the driving transistor, the first light emission transistor configured to perform a switching operation based on a first light emission signal;
an inverter configured to invert the first light emission signal to generate a second light emission signal;
an organic light emitting diode configured to emit light based on the driving current; and
a bypass transistor including a source electrode connected to an anode electrode of the organic light emitting diode, the bypass transistor configured to perform a switching operation based on the second light emission signal.

2. The pixel as claimed in claim 1, wherein:
a drain electrode of the bypass transistor is connected to a first voltage source supplying an initialization voltage, and
the bypass transistor is turned on based on the second light emission signal to allow leakage current to flow along a bypass signal path.

3. The pixel as claimed in claim 2, further comprising:
a storage capacitor connected between a gate of a first driving transistor and a second voltage source.

4. The pixel as claimed in claim 3, further comprising:
an initialization transistor connected between a gate electrode of the driving transistor and the first voltage source, the initialization transistor configured to perform a switching operation based on a second scan signal.

5. The pixel as claimed in claim 4, further comprising:
a compensation transistor connected to the gate electrode and the drain electrode of the driving transistor, the compensation transistor configured to perform a switching operation based on the first scan signal.

6. The pixel as claimed in claim 5, wherein:
each of the first and second scan signals include an enable pulse, and
the enable pulse of the second scan signal is before the enable pulse of the first scan signal.

7. The pixel as claimed in claim 1, further comprising:
a second light emission transistor connected between a source of the driving transistor and the first voltage source, the second light emission transistor to perform a switching operation based on to the first light emission signal.

8. The pixel as claimed in claim 7, wherein the first light emission transistor and the second light emission transistor are turned on after the data signal is transmitted.

9. A method of driving a pixel, the method comprising:
turning off a first light emission transistor and a second light emission transistor based on a first light emission signal;
generating a second light emission signal inverted from the first light emission signal; and
turning on a bypass transistor based on the second light emission signal, wherein turning on the bypass transistors allows leakage current to flow through the bypass transistor along a bypass signal path.

10. The method as claimed in claim 9, further comprising:
turning on a switching transistor based on a first scan signal;
turning on a compensation transistor according to the first scan signal; and
transmitting a data signal to a gate electrode of a driving transistor through the turned-on switching transistor and compensation transistor.

11. The method as claimed in claim 10, further comprising:
maintaining a voltage corresponding to the data signal transmitted to the gate electrode of the driving transistor in a storage capacitor based on the data signal.

12. The method as claimed in claim 11, further comprising:
turning on an initialization transistor based on the second scan signal; and
transmitting an initialization voltage to the gate electrode of the driving transistor.

13. The method as claimed in claim 12, wherein transmitting the initialization voltage is performed before the switching transistor and the compensation transistor are turned on.

14. The method as claimed in claim 10, further comprising:
after the data signal is transmitted to the gate electrode of the driving transistor, emitting light from an organic light emitting diode based on driving current flowing through the driving transistor.

15. A display device comprising:
a plurality of scan lines, a plurality of light emission control lines, and a plurality of data lines; and
a plurality of pixels connected to the scan lines, the light emission control lines, and the data lines, wherein the pixel includes:
a switching transistor including a source electrode connected to a data line, the switching transistor configured to perform a switching operation according to a first scan signal;
a driving transistor including a source electrode connected to a drain electrode of the switching transistor, the driving transistor configured to control a driving current according to a data signal transmitted when the switching transistor is turned on;
a first light emission transistor including a source electrode connected to a drain electrode of the driving transistor, the first light emission transistor configured to perform a switching operation according to a first light emission signal;
an inverter configured to invert the first light emission signal to generate a second light emission signal;
an organic light emitting diode configured to emit light according to the driving current; and
a bypass transistor including a source electrode connected to an anode electrode of the organic light emitting diode, the bypass transistor configured to perform a switching operation according to the second light emission signal.

16. The display device as claimed in claim 15, wherein:
a drain electrode of the bypass transistor is connected to a first voltage source supplying an initialization voltage, and
the bypass transistor is turned on based on the second light emission signal to allow leakage current to flow along a bypass path.

17. The display device as claimed in claim 16, further comprising:
a storage capacitor connected between a gate of a first driving transistor and a second voltage source.

18. The display device as claimed in claim 17, further comprising:
an initialization transistor connected between a gate electrode of the driving transistor and the first voltage source, the initialization transistor configured to perform a switching operation based on a second scan signal.

19. The display device as claimed in claim 18, further comprising:
a compensation transistor connected to the gate electrode and the drain electrode of the driving transistor, the compensation transistor configured to perform a switching operation based on the first scan signal.

20. The display device as claimed in claim 19, wherein:
each of the first and second scan signals include an enable pulse, and
the enable pulse of the second scan signal before the enable pulse of the first scan signal.

21. The display device as claimed in claim 20, wherein:
a second light emission transistor connected between a source of the driving transistor and the second voltage source, wherein the second light emission transistor performs a switching operation based on to the first light emission signal.

22. The display device as claimed in claim 21, wherein the first light emission transistor and the second light emission transistor are turned on after the data signal is transmitted.

23. A pixel, comprising:
a first transistor;
an organic light emitting diode; and
a second transistor having a terminal connected between the first transistor and the organic light emitting diode, wherein the first transistor is a driving transistor and the second transistor controls flow of leakage current along a signal path that bypasses the organic light emitting diode.

24. The pixel as claimed in claim 23, wherein the second transistor controls flow of leakage current along the bypass signal path during an initialization period of the driving transistor.

25. The pixel as claimed in claim 23, wherein the second transistor controls flow of leakage current along the bypass signal path during a scan period.

26. The pixel as claimed in claim 23, wherein the second transistor is controlled based on a light emission signal.

27. The pixel as claimed in claim 23, wherein the second transistor is controlled based on an inverted logical value of a light emission signal.

28. The pixel as claimed in claim 23, wherein the bypass signal path is coupled to a voltage source.

29. The pixel as claimed in claim 28, wherein the voltage source is an initialization voltage source.
